(19) United States
(12) Patent Application Publication
(10) Pub. No.: US 2019/0340962 A1
(43) Pub. Date: Nov. 7, 2019

(54) Spinning LED Image Smoothing

(71) Applicant: Smoothweb Technologies Limited, Hong Kong (HK)

(72) Inventor: Rajiv Trehan, Loncon (GB)

(21) Appl. No.: 15/972,965

(22) Filed: May 7, 2018

(51) Int. Cl. G09G 3/00; H01L 25/075; G09F 9/33; G09F 19/12

(52) U.S. Cl. CPC G09G 3/001; H01L 25/0753; G09G 2370/16; G09F 19/12; G09G 2300/04; G09F 9/33

(57) ABSTRACT

A persistence of vision display is disclosed by the present invention. A system and method is disclosed for displaying Spinning LED Image to a viewer without any pixel gaps. The system and method includes offsetting pixels for the light emitting elements of one array of arms by a fraction of distance between pixels by the light emitting elements of second array of alternatives arms in spinning configuration, where a pixel gap between concentric rings formed by the one array of arms is filled by offsetting pixels of the light emitting elements of the second array of alternatives arms.

### FIELD OF THE INVENTION

This invention relates to the field of LED display based on the rotating principle of persistence of vision, more particularly methods and systems for smoothing LED image display.

### BACKGROUND OF THE INVENTION

LED display such as for digital information displays, entertainment displays; and advertising and marketing image displays with arrays of light-emitting diodes (LEDs), or other discrete light sources, are well known in the art.

It has been found that, where it is desirable to display an image, a rotary display is being used. Such rotary display typically comprises planner or vertical light-emitting diodes (LEDs) which is rotated about it axis in an appropriate sequence and at an appropriate rate, so as to present a fixed image to a viewer using the persistence of vision. Further, the rotary display typically has greater appeal to a viewer than a conventional display and has been largely used in the fields of advertising and marketing display.

U.S. patent application Ser. No. 12/652,526 discloses a method and apparatus for displaying digital data comprising a rotary display which displays the digital data as a 360 degree translucent or transparent floating image. The rotary display utilizes a vertical array of light-emitting elements which is rotated on an arm about a center axis, and pulsed in an appropriate sequence and at an appropriate rate, so as to present a fixed image to a viewer using the “persistence of vision” phenomenon associated with the human eye.

U.S. patent application Ser. No. 15/128,047 discloses a persistence of vision display comprising a processing unit, a plurality of light arrays each independently electrically connected to said processing unit, wherein the processing unit is adapted to control the output displayed on each array independently. The light arrays are adapted to be moved so as to generate a persistence of vision image; preferably wherein the movement is a rotational movement. Where, the processing unit is adapted to control the output displayed on each array by providing data and/or instructions to each array.

U.S. patent application Ser. No. 15/410,455 discloses apparatuses and methods for displaying a 3-D representation of an object. A pparatuses include a rotatable structure, motor, and multiple light field sub-displays disposed on the rotatable structure. The apparatuses can store a light field image to be displayed, the light field image providing multiple different views of the object at different viewing directions.

U.S. patent application Ser. No. 13/591,400 discloses a three-dimensional display device includes a rotatable portion and a plurality of light emitting elements connected to the rotatable portion. Rotation of the rotatable portion rotates the light emitting elements and displays an illusion of a three-dimensional image corresponding to a sequence of segmented images.

U.S. patent application Ser. No. 1/168,057 discloses a device for displaying an image. The device includes a hub that is configured to rotate about a first axis and a motor configured to rotate the hub about the first axis. A plurality of light detecting devices attached to the hub and at least one lens configured to direct light toward the light detecting devices.

The light emitting diodes (LEDs) are discrete lights spaced apart to form a matric of lights, the resolution of these displays often measured in the distance between LED. For larger or brighter the LED are typically further apart and displays tend to be relatively coarse. The existing rotatory displays provide image surface which appears transparent for off pixels and show an image for on pixels. However, the gap between pixels can be seen as concentric rings. The solution to this is to use denser pixel, which can be very expensive for large displays and further brightness counter balance to the density of the pixels is complicated and expensive.

As a result, there is a need for a new and improved rotary display systems and method by offsetting the pixels on the array of light emitting diodes (LEDs) by a fraction of the distance between pixels and in which the pixel pitch of the rotating pixels on alternative array of light emitting diodes (LEDs) arms will fill in the gaps. Therefore, the concentric rings left by one array will be filled in by the pixels on the second array and the plane of the display can display only the images without any pixel gap.

### SUMMARY OF THE INVENTION

The present invention provides a new system and method for displaying Spinning LED Image. According to one aspect of the present invention, there is provided a LED spinning system for displaying digital content to a viewer without any pixel gaps.

According to one aspect of the invention, there is provided a LED spinning system comprising an array of light emitting diodes (LEDs) arms connected at a center Hub, a plurality of light-emitting elements that are equally spaced on each arm and a processing unit. Where the LED spinning system is configured for offsetting pixels by the light emitting elements on one array of arms by a fraction of distance between pixels respective to second array of arms (alternative arms) in spinning, where the one array of arms produce concentric rings in which a pixel gap created by the light emitting elements on the one array of arms is filled by the pixel of the light emitting elements on alternative arms, and the array of light emitting diodes (LEDs) arms are connected to the processing unit and the processing unit is operable to control and display LED images without any pixel gap.

According to one aspect of the invention there is provided a LED spinning system presents a fixed image to a viewer using the “persistence of vision” phenomenon associated with the human eye, whereby to provide display image which is viewable from all angles.

According to another aspect of the invention, a method for smoothing the display Image for the LED spinning system by offsetting the pixels by the light emitting elements on alternative arms by a fraction of the distance between pixels on the light emitting elements on one array of arms and in which the pixel pitch of the rotating pixels on alternative arms for light emitting elements is filled in the gaps created by the one array of arms. That is the gaps left by one array arm will be filled in by the concentric ring formed by the pixels on the second array and the plane of the display can display the images without any pixel gap.

### BRIEF DESCRIPTION OF THE DRAWINGS

The following invention will be described with reference to the following drawings of which:

FIG. 1 is a schematic perspective view of an array of light emitting diodes (LEDs) arms connected at a center Hub;

FIG. 2 is a schematic perspective view of an array of light emitting diodes (LEDs) arms with light emitting elements;

FIG. 3 is a schematic perspective view of pixel gaps between the concentric rings formed when spinning the array of light emitting diodes (LEDs) arms in accordance with the FIG. 2;

FIG. 4 is a schematic perspective view of a LED spinning system formed in accordance with the present invention;

FIG. 5 is a schematic perspective view of a LED spinning system of FIG. 4, in which offsetting pixels between the concentric rings formed when spinning the an array of light emitting diodes (LEDs) arms in accordance with the present invention; and

FIG. 6 is schematic block diagram of various components of the LED spinning system in accordance present invention.

The drawing figures do not limit the present invention to the specific embodiments disclosed and described herein. The drawings are not necessarily to scale; emphasis instead is placed upon clearly illustrating the principles of the invention.

### DETAILED DESCRIPTION OF THE INVENTION

The invention can be implemented in numerous ways, including as a method, an apparatus, a system and a computer readable medium such as a computer readable storage medium or a computer network wherein program instructions are sent over communication links. In this disclosure, these implementations, or any other form that the invention may take, may be referred to as techniques. A component such as a processor or a memory described as being configured to perform a task includes both a general component that is temporarily configured to perform the task at a given time and a specific component that is manufactured to perform the task. In general, the order of the steps of disclosed system and method may be altered within the scope of the invention.

Although the following detailed description contains many specifics for the purposes of illustration, anyone of ordinary skill in the art will appreciate that many variations and alterations to the following details are within the scope of the invention. Accordingly, the following preferred embodiments of the invention are set forth without any loss of generality to, and without imposing limitations upon, the claimed invention.

Following below are more detailed descriptions of systems and methods of the present invention. In one embodiment of the present invention provide a LED spinning system for “persistence of vision” to be attached to a rotatable structure.

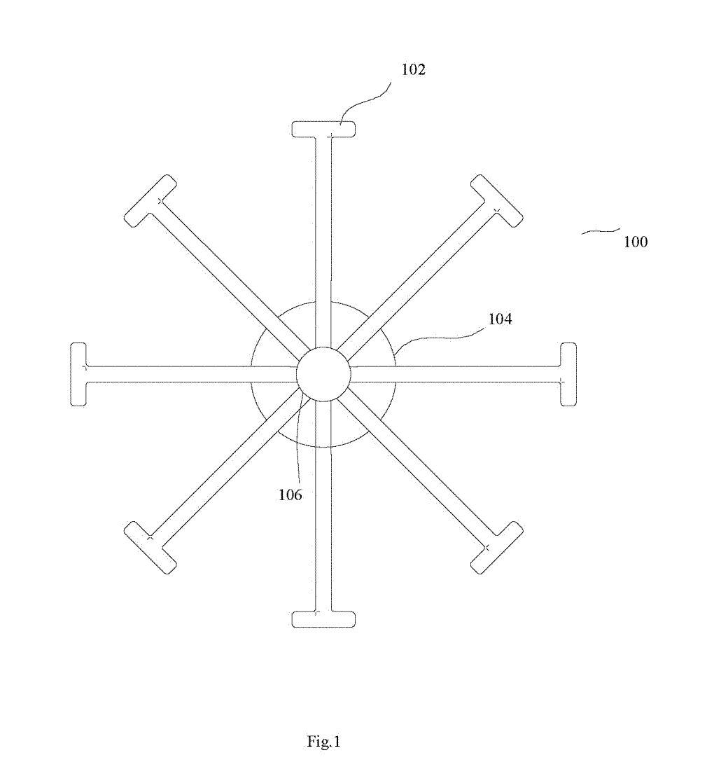

Now referring to FIGS. 1 to 5, in one exemplary embodiment of the present invention provides a LED spinning system 100 comprising an array of light emitting diodes (LEDs) arms 102 and a processing unit 104. The LED spinning system 100 is adapted to display digital data as a translucent or transparent LED image. The LED spinning system 100 comprises of an array of light emitting diodes (LEDs) arms 102 connected at a center Hub 106 and which is rotated on a rotatable structure about a center axis (not shown in the figures), and at an appropriate speed, so as to present a fixed LED image to a viewer using the “persistence of vision” phenomenon associated with the human eye, whereby to display LED image which is viewable from all angles.

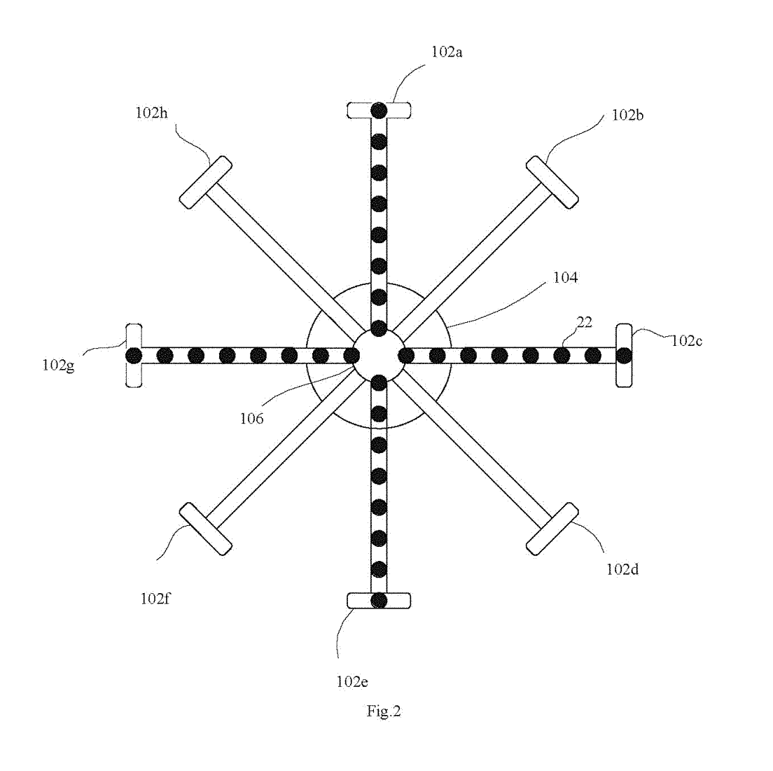

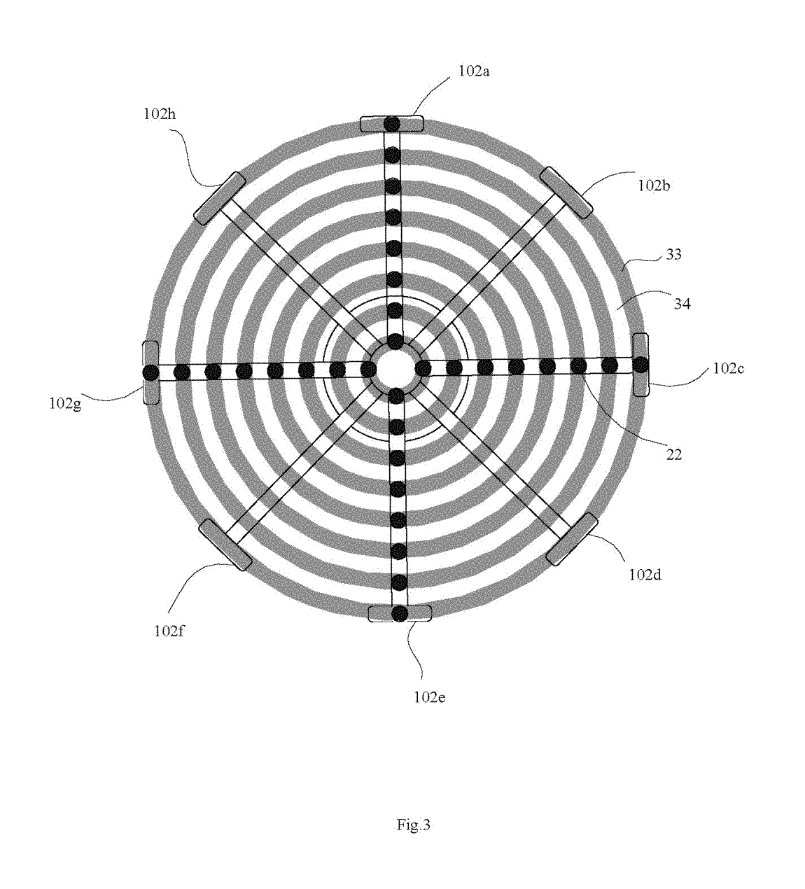

As shown in the FIGS. 1 to 5, in one exemplary embodiment, the arms 102 may be more or less without departing form the scope of the present invention. Further, in one exemplary embodiment, as shown in the FIGS. 1 to 5, the arms 102 are equally spaced to provide display image without limiting the scope of the present invention. Further, each arm 102 includes a plurality of light-emitting elements e.g. light emitting diodes (LEDs) that are equally spaced on the arms. Further as shown in FIG. 2, in one exemplary embodiment, each alternative arms, for example arms 102a, 102c, 102e and 102g include a plurality of light-emitting elements 22 that are equally spaced on the arms 102a, 102c, 102e and 102g to form concentric rings when spinning the system 100 on the rotatable structure. The concentric rings 33 are shown in FIG. 3 as in an exemplary embodiment. However, in FIG. 3, it can be seen that there is gaps 34 in the pixel pitch between the concentric rings 33.

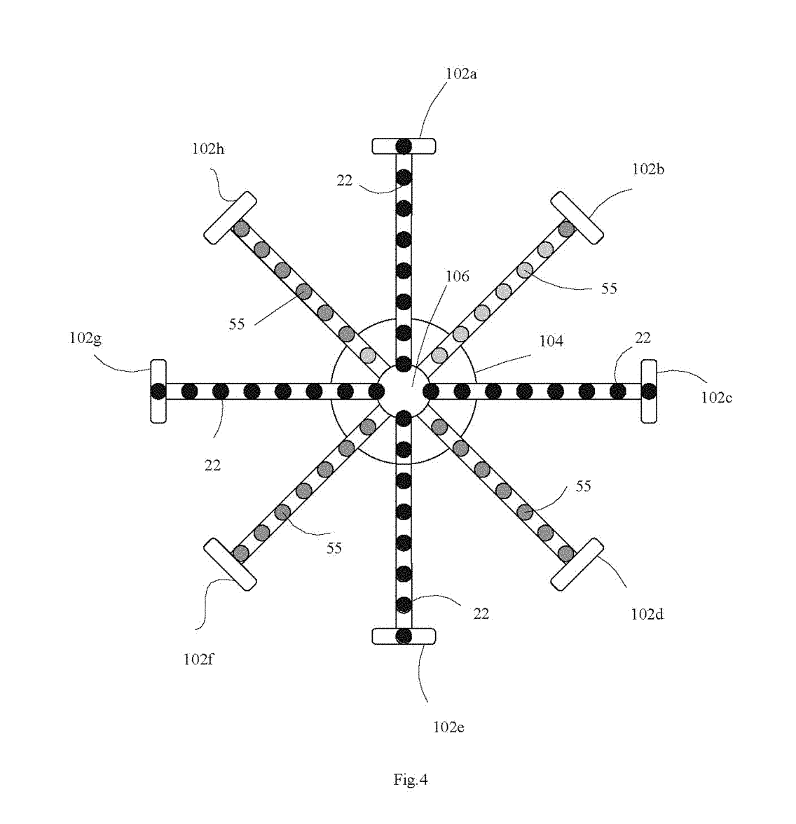

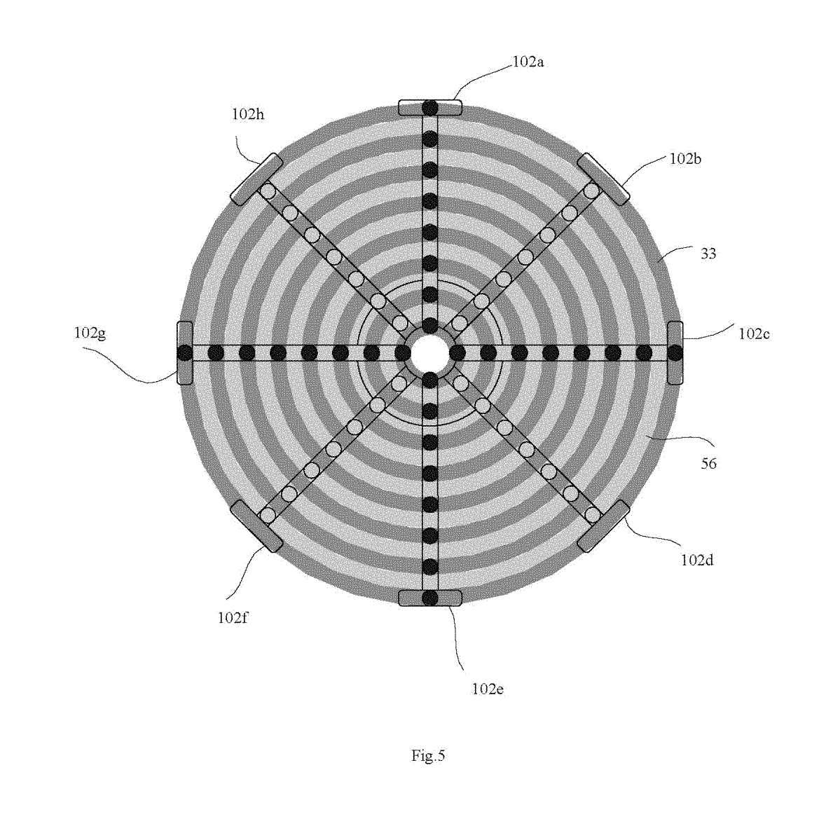

As a result, in one preferred embodiment of the present invention provides a method for smoothing the display Image for the LED spinning system 100 by offsetting the pixels on the arms 102 for light emitting elements 22 by a fraction of the distance between pixels and in which the pixel pitch of the rotating pixels on alternative arms 102 for light emitting elements will fill in the gaps 34. As shown in FIGS. 4 and 5, the gaps 34 in the pixel is filled by the light emitting elements 55 of each alternative arms 102b, 102d, 102f, and 102h. Therefore, the gaps 34 left by one array of arms 102a, 102c, 102e and 102g is filled in by the concentric ring 56 formed by the pixels of the light emitting elements 55 on the second array of arms 102b, 102d, 102f and 102h and the plane of the display can display the images without any pixel gap.

For illustrative purpose, the light emitting elements 22 on one array of arms 102a, 102c, 102e, and 102g are depicted in dark grey colour. Further the light emitting elements 55 on the second array of arms (alternative arms) 102b, 102d, 102f, and 102h are depicted in light grey colour. Further the concentric rings 33 formed by the light emitting elements 22 on one array of arms 102a, 102c, 102e, 102g are depicted in dark grey colour and the concentric rings formed by the light emitting elements 55 on the second array of arms (alternative arms) 102b, 102d, 102f, 102h are depicted in light grey colour. Those of skill in the art will readily recognize that there are many variations which implement equivalent functions and the illustrative embodiments are made for illustrative purpose only.

Each arm 102 has at least two or more row of light emitting elements 22, 55 on its outer-facing face; preferably, these are light emitting diodes (LEDs), more preferably, multi-colour LEDs. The spacing of the light emitting elements 22, 55 along the entire length of the arm 102 allows for an image to fill the maximum area within a rotating structure. The distance between each light emitting elements and the absolute dimension of the elements 22, 55 determine the maximum achievable resolution. The variety in colour operable to be displayed is also limited by the density of light emitting elements 22, 55, and the number of individual colours each light emitting element 22, 55 can display. Therefore, it is advantageous to have as many light emitting elements 22, 55 as possible on each arm 102 to enable a large, high-resolution image to be displayed.

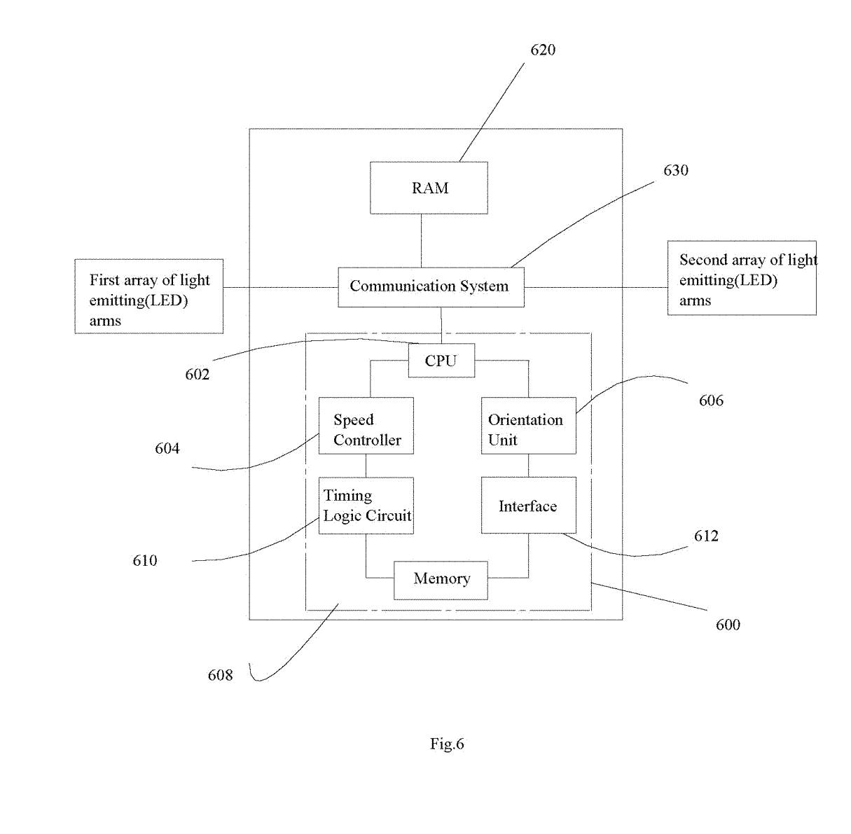

As discussed above, in one embodiment, there are two sets of arm, each alternative arms are grouped into one array of arms 102a, 102c, 102e and 102g and further other alternative arms are grouped in second array 102b, 102d, 102f and 102h. Accordingly, the light-emitting elements 22 are attached to one array of arm 102a, 102c, 102e and 102g at equally spaced distances and the light-emitting elements 55 are attached to equally spaced distances by a fraction of the distance between pixels with one array of arms 102a, 102c, 102e and 102g and second array of arms 102b, 102d, 102f and 102h as shown in FIGS.5 and 6. In this arrangement, the gaps 33 left by the one array of arms 102a, 102c, 102e and 102g is filled in by the pixels of the light emitting elements 55 of the second array of arms 102b, 102d, 102f and 102h and the plane of the display can display the images without any pixel gap.

Further in one preferred embodiment of the present invention, a method to overcome the small gap 33 in the pixel while rotating the LED spinning system 100 by offsetting the pixels of the light-emitting elements 55 on the array of light emitting diodes (LEDs) arms 102b, 102d, 102f and 102h by a fraction of the distance between pixels in the light-emitting elements 22 one array of arm 102a, 102c, 102e and 102g and in which the pixel pitch of the rotating pixels on alternative array of light emitting diodes (LEDs) arms 102b, 102d, 102f and 102h will fill in the gaps as shown in FIG. 4.

Further, in another embodiment the LED spinning system 100 comprises the processing unit 104 which includes a central processing unit example a processor and the processor is either pre-loaded with display content or display contents are transferred during device operation, via a wireless (e.g., cellular telephone, Wi-Fi, Bluetooth, etc.) connection. When spinning the LED spinning system 100, the processor unit senses the rotating speed and rotation angle for employing the orientation of the display. Using the orientation of each arm 102 and speed of rotation, the processing unit 104 can determine the orientation of each light-emitting element 22,55 (such as Light Emitting Diodes (LEDs)) on each arm 102 accordingly so as to produce a persistence of vision display.

Now referring to FIG. 6 is a schematic of the LED spinning system where the processing unit 104 comprises a central control board 600, RAM 620 and communication system 630. The central control board 600 comprises a central processing unit (CPU) 602, a speed controller 604, an orientation unit 606, memory 608, a timing logic circuit 610 and an interface 612. The speed controller 604 receives speed information and passes this information to the processor 602 which determines whether the rotational speed of the device 100 is above a pre-determined threshold before activating the display. The speed information from the speed controller 604 is also sent to orientation unit 606 which is operable to calculate the position of each array 102 in real time. The orientation unit 606 receives signals and passes this information to the communication system 630 which determines the orientation of the system 100. In use, data relating to at least one display pattern (such as images and/or videos) to be displayed by the system 100 and programs adapted to cause said display pattern to be output for display is stored in memory 608. Alternatively, this processing may be performed by the processor 602; the graphics may be in any format for further processing. The processor 602 fetches images to be displayed from memory 608 and sends them to the Random-Access Memory (RAM) connected to the communication system 630. The communication system 630 then determines the speed and position of each light array 106 it controls (using the signal from the speed and/or orientation unit) and the corresponding pattern to be displayed in real-time to selectively activate the arrays 102 (or portions thereof) at predetermined times thereby to display the stored display pattern. Furthermore, splitting the processes of fetching the data relating to the display pattern (performed by the central processor) and activating the appropriate light arrays allows for a much greater resolution of display to be produced relative to the existing system and method available in the prior art.

Further, information may be programmed into the memory 608 via BUS interface 612. This may be a wired connection so that a user can program the memory with specific images and/or video via a user interface on a personal computer. Alternatively, it may be a wireless link such as Bluetooth®, WiFi® or Near Field Communication,) and a mobile device (such as a smartphone or tablet) can be used to program the memory 608. The memory 608 is preferably non-volatile so that information stored in the memory. Examples of such non-volatile memory include Erasable Programmable Read-Only Memory (EPROM), Electrically Erasable Programmable Read-Only Memory (EEPROM), or Flash memory (which is preferable).

The system 100 may further comprise a Global Positioning System (GPS) unit so that it can be remotely uploaded and controlled. The system 100 may also be programmed to display location-based images for businesses/advertising.

Certain embodiments are described herein as including logic or a number of components, modules, or program. Modules may constitute either software modules (e.g., code embodied on a machine-readable medium or in a transmission signal) or hardware modules. A hardware module is a tangible unit capable of performing certain operations and may be configured or arranged in a certain manner. In example embodiments, one or more computer systems (e.g., a standalone, client, or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. Accordingly, the term “hardware module” should be understood to encompass a tangible entity, be that an entity that is physically configured to operate in a certain manner and/or to perform certain operations described herein. The one or more processors may also operate to support performance of the relevant operations in a “cloud computing” environment or as a “software as a service” (SaaS).

A computer program can be written in any form of programming language, including compiled or interpreted languages, and it can be deployed in any form, including as a standalone program or as a module, subroutine, or other unit suitable for use in a computing environment. A computer program can be deployed to be executed on one computer or on multiple computers at one site, or distributed across multiple sites and interconnected by a communication network.

Further in another exemplary embodiment a motor is provided which rotates the system 100 which are affixed to a rotating structure (Not shown in Figures). Further, in another embodiment, the system 100 produces the visually impressive effect of the displayed image appearing transparent image seemingly without any pixel gap. The present embodiment which is not necessarily affixed to an external structure may comprise some or all features from the above embodiment which is described affixed to a rotating structure. In one example, the light arrays and the processing unit are powered via an external power source (not shown).

One skilled in the art will appreciate that the embodiments provided above are exemplary and in no way limit the present invention.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such features may be combined with one or more other features of the other implementations as may be desired and advantageous for any given or particular application.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

The Abstract of the disclosure will allow the reader to quickly ascertain the nature of the technical disclosure. It is submitted with the understanding that it will not be used to interpret or limit the scope or meaning of the following claims.

1. A system for LED image smoothing for a persistence of vision display; comprising:
an array of light emitting diodes (LEDs) arms connected at a center Hub;
a plurality of light-emitting elements are equally spaced on each light emitting diodes (LEDs) arm; and
a processing unit,
wherein offsetting pixels by the light emitting elements of one array of arms by a fraction of distance between pixels by the light emitting elements of second array of alternatives arms in spinning configuration, where a pixel gap in concentric rings formed by the one array of arms is filled by the offsetting pixels of the light emitting elements of the second array of alternatives arms, and the array of light emitting diodes (LEDs) arms is connected to the processing unit and the processing unit is operable to control and display LED images without the pixel gap.

2. The system of claim 1, wherein the array of light emitting diodes (LEDs) arms connected at the center Hub is rotated on a rotatable structure about a center axis.

3. The system of claim 1, wherein the light emitting diodes (LEDs) arms are equally spaced by connecting to the center Hub.

4. The system of claim 1, wherein the light emitting diodes (LEDs) arms are equally-angularly-spaced from one another.

5. The system of claim 1, further comprising a motor to rotate the rotating structure to display spinning LED image.

6. The system of claim 1, wherein the array of light emitting diodes (LEDs) arms form a circular plane.

7. The system of claim 1, wherein the light emitting elements of the one array of arms are offset by a fraction of distance from the light emitting elements of the second array of alternatives arms.

8. The system of claim 1, wherein the light emitting elements of one arm are offset from the light-emitting elements of the adjacent arms.

9. The system of claim 1, wherein the light emitting elements comprise light-emitting diodes (LEDs).

10. The system of claim 1, wherein the system is configured to receive digital content transferred via a wireless connection to the processing unit.

11. The system of claim 1, wherein the system is configured to receive digital content transferred via a Wi-Fi connection to the processing unit.

12. The system of claim 1, wherein the system is configured to receive digital content transferred via a Bluetooth connection to the processing unit.

13. The system of claim 1, wherein the processing unit comprises a memory for storing digital content to be displayed by the system.

14. A method for LED image smoothing for a persistence of vision display; comprising:
providing an array of light emitting diodes (LEDs) arms connected at a center Hub;
fixing a plurality of light-emitting elements are equally spaced on each light emitting diodes (LEDs) arm;
performing offsetting pixels for the light emitting elements of one array of arms by a fraction of distance between pixels by the light emitting elements of second array of alternatives arms in spinning configuration, where a pixel gap between concentric rings formed by the one array of arms is filled by the offsetting pixels of the light emitting elements of the second array of alternatives arms; and
controlling and displaying the LED images without the pixel gap by a processing unit, where the array of light emitting diodes (LEDs) arms are connected to the processing unit.

15. The method of claim 14, wherein the light emitting elements of the one array of arms are offset by a fraction of distance from the light emitting elements of the second array of alternatives arms.

16. The method of claim 14, wherein digital content is transmitted from a remote source to the processing unit.

17. The method of claim 14, wherein a motor performs spinning the array of light emitting diodes (LEDs) arms connected at the center Hub on a rotatable structure.
